(19) United States
(12) Patent Application Publication
(10) Pub. No.: US 2001/0023082 A1
(43) Pub. Date: Sep. 20, 2001

(54) Grind and single wafer etch process to remove metallic contamination in silicon wafers

(76) Inventors: Krishna Vepa, Livermore, CA (US); Duncan Dobson, Woodside, CA (US)

Correspondence Address: TOWNSEND AND TOWNSEND AND CREW, TWO EMBARCADERO CENTER, EIGHTH FLOOR, SAN FRANCISCO, CA, 94111-3834, US

(21) Appl. No.: 09/808,736

(22) Filed: Mar. 15, 2001

Related U.S. Application Data
(60) Provisional application No. 60/190,478, filed on Mar. 17, 2000.
(60) Provisional application No. 60/190,276, filed on Mar. 17, 2000.

(51) Int. Cl. H01L 21/66

(52) U.S. Cl. 438/14

(57) ABSTRACT

The present invention provides systems and methods for grinding wafers for use in manufacturing semiconductor devices. The methods include grinding a semiconductor wafer such that the grind pattern on the wafer is less than ten (10) microns deep. Then, the wafer is etched using an acid etchant. During the etch, less than twenty (20) microns of semiconductor material is removed from a combination of the front and the back of the wafer. In addition, metallic contamination is removed from the wafer. The system includes an integrated grinder and etcher for processing single wafers.

### CROSS-REFERENCES TO RELATED APPLICATIONS

This application claims the benefit of the following U.S. Applications, the complete disclosures of which are incorporated herein by reference for all purposes:

Non-Provisional Application No. ______ (Attorney Docket No. 20468-000210), entitled “Systems and Methods to Significantly Reduce the Grinding Marks in Surface Grinding of Semiconductor Wafers” and filed on a date even herewith;

Provisional Application No. 60/190,478 (Attorney Docket No. 20468-000200), filed on Mar. 17, 2000; and

Provisional Application No. 60/190,276 (Attorney Docket No. 20468-000500), filed on Mar. 17, 2000.

### BACKGROUND OF THE INVENTION

The present invention is directed to the processing of wafers, substrates or disks, such as silicon wafers, and more specifically to integrated grind and etch methods and systems for preparing semiconductor wafers.

Wafers or substrates with exemplary characteristics must first be formed prior to the formation of circuit devices. In determining the quality of the semiconductor wafer, the flatness of the wafer is a critical parameter to customers since wafer flatness has a direct impact on the subsequent use and quality of semiconductor chips diced from the wafer. Hence, it is desirable to produce wafers having as near a planar surface as possible.

In a current practice, cylindrical boules of single-crystal silicon are formed, such as by Czochralski (CZ) growth process. The boules typically range from 100 to 300 millimeters in diameter. These boules are cut with an internal diameter (ID) saw or a wire saw into disc-shaped wafers approximately one millimeter (mm) thick. The wire saw reduces the kerf loss and permits many wafers to be cut simultaneously. However, the use of these saws results in undesirable waviness of the surfaces of the wafer. For example, the topography of the front surface of a wafer may vary by as much as 1-2 microns (μ) as a result of the natural distortions or warpage of the wafer as well as the variations in the thickness of the wafer across its surface. It is not unusual for the amplitude of the waves in each surface the wafer across its surface. It is not unusual for the amplitude of the waves in each surface of a wafer to exceed fifteen (15) micrometers. The surfaces need to be made more planar (planarized) before they can be polished, coated or subjected to other processes.

FIG. 1 depicts a typical prior art method 10 for processing a silicon wafer prior to device formation. Method 10 includes a slice step 12 as previously described to remove a disc-shaped portion of wafer from the silicon boule. Once the wafer has been sliced, the wafer is cleaned and inspected (Step 14). Thereafter, an edge profile process (Step 16) is performed. Once the edge profile has been performed, the wafer is again cleaned and inspected (Step 18), and is laser marked (Step 20).

Next, a lapping process (Step 22) is performed to control thickness and remove bow and warp of the silicon wafer. The wafer is simultaneously lapped on both sides with an abrasive slurry in a lapping machine. The lapping process may involve one or more lapping steps with increasingly finer polishing grit.

The wafer is then cleaned (Step 24) and etched (Step 26) to remove damage caused by the lapping process. Typically, the etchant is a material requiring special handling and disposal. The etching process may involve placing the wafer in a caustic or acid bath to remove the outer surface of the wafer damaged during the lapping process. For example, a traditional etch may remove between twenty-five (25) and forty (40) microns of material from the wafer surface. Removing such significant amounts of wafer material is both wasteful and requires significant processing time. Further, removing such large amounts of material through the etch process seriously degrades the shape of the wafers. This is particularly true near wafer edges where surface exposure to the etchants is higher than on the front and back sides of the wafers.

Thereafter, an additional cleaning of the wafer (Step 28) is performed. The cleaning step is required to remove metallic contamination of the wafer introduced in the prior processing steps.

The prior art method continues with a donor anneal (Step 30) followed by wafer inspection (Step 32). Thereafter, the wafer edge is polished (Step 24) and the wafer is again cleaned (Step 36). Typical wafer processing involves the parallel processing of a multitude of wafers. Hence at this juncture wafers may be sorted, such as by thickness (Step 38), after which a double side polish process is performed (Step 40).

The wafers then are cleaned (Step 42) and a final polish (Step 44) is performed. The wafers are again cleaned (Step 46), inspected (Step 48) and potentially cleaned and inspected again (Steps 50 and 52). For epitaxial substrates, a poly or oxide layer is overlaid to seal in the dopants after inspection Step 52. At this point, the wafer is packed (Step 54), shipped (Step 56) and delivered to the end user (Step 58). Hence, as seen in FIG. 1 and as described above, typical wafer processing involves a lengthy, time consuming process with a large number of processing steps.

A number of deficiencies exist with the prior art method. As can be seen from even a precursory review of FIG. 1, the prior art method requires a large number of steps to transform a wafer slice into a substrate suitable for creating circuit devices. The large number of process steps involved negatively effects production throughput, requires a large production area, and results in high fabrication costs. Additionally, each of the steps in FIG. 1 are typically performed at individual process stations. The stations are not grouped or clustered together, and manual delivery of the wafers between stations is often used.

In addition to the large number of process steps, the etch step of the prior art is particularly slow and leads to unacceptable results. For example, the etch step requires significant time to remove the required twenty-five (25) forty (40) microns of wafer material. Further, the etch process often results in serious shape degradation, in part attributable to the amount of wafer material removed. In addition, the wafer must be cleaned after the etch to remove metallic contamination introduced in prior processing steps.

Additional deficiencies in the prior art, and improvements in the present invention, are described below and will be recognized by those of ordinary skill in the art.

### SUMMARY OF THE INVENTION

The present invention provides systems and methods for grinding wafers for use in manufacturing semiconductor devices. The methods include grinding a wafer such that the grind pattern on the wafer is less than ten (10) microns deep. After the grind, the wafer is etched using an acid etchant. During the etch, less than twenty (20) microns of semiconductor material is removed from a combination of the front and the back of the wafer. In addition, metallic contamination is leached from the wafer. In some embodiments, the acid etchant comprises HF and HNO₃.

In some embodiments, the depth of the grind pattern is less than about seven (7) microns and etching the wafer removes less than about fourteen (14) microns of wafer material from a combination of the front and the back side of the wafer. Removing such a small amount of wafer material reduces shape degradation of the wafer. Thus, in embodiments where the wafer is 200 millimeters or larger, the flatness of the wafer can be between about 0.3 microns and about 0.5 microns. In other embodiments where the wafer is 300 millimeters or larger, the flatness of the wafer can be between about 0.4 microns and about 0.7 microns.

Some embodiments of systems according to the present invention are useful for providing wafers which are substantially free of metallic contamination without requiring a separate post grind cleaning step. Such systems include a grinder capable of flattening the wafer face and leaving a grind pattern less than ten (10) microns deep. The wafer is placed in an etchant bath integrated with the grinder. A transfer mechanism under microprocessor control is used to transfer the wafer from the grinder to the etchant bath. Microprocessor control is provided based on computer executable code maintained in a database associated with the microprocessor. In some embodiments, the metallic contamination includes iron (Fe) and copper (Cu) metal.

Other objects, features and advantages of the present invention will become more fully apparent from the following detailed description, the appended claims and the accompanying drawings.

### BRIEF DESCRIPTION OF THE DRAWINGS

FIG. 1 depicts a prior art method for processing a silicon wafer;

FIG. 2 is a simplified flow diagram of a wafer processing method according to the present invention;

FIGS. 3A-C depict grind damage cluster tools according to the present invention;

FIG. 4 depicts an edge profile/polish cluster tool according to the present invention;

FIGS. 5A and 5B depict double side polish cluster tools according to the present invention;

FIG. 6 depicts a finish polish cluster tool according to the present invention;

FIG. 7 is a simplified schematic of a wafer grinding apparatus which may be used in accordance with the present invention;

FIG. 8 depicts a simplified flow diagram of an embodiment of a wafer grinding method according to the present invention; and

FIG. 9 depicts an integrated wafer grind machine and etchant bath according to the present invention.

### DESCRIPTION OF THE SPECIFIC EMBODIMENTS

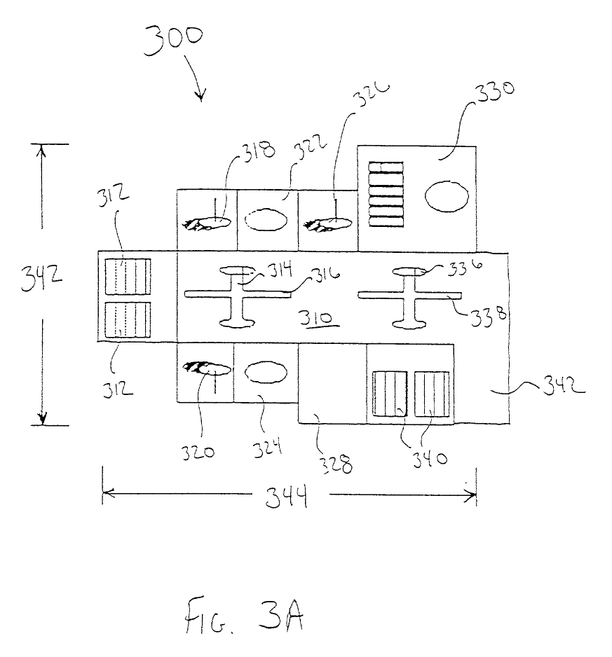

FIG. 2 depicts an exemplary method 200 of the present invention. Additional details of exemplary methods may be found in U.S. patent application Ser. No. ______ (Attorney Docket No. 20468-000110), entitled “Cluster Tool Systems and Methods for Processing Wafers,” the complete disclosure of which is incorporated herein by reference for all purposes. Method 200 includes a slice process 210, using a wire saw, inner diameter saw or the like, to create a generally disc-shaped wafer or substrate. In one embodiment, the wafer is a silicon wafer. Alternatively, the wafer may comprise polysilicon, germanium, glass, quartz, or other materials. Further, the wafer may have an initial diameter of about 200 mm, about 300 mm, or other sizes, including diameters larger than 300 mm.

The wafer is cleaned and inspected (Step 212) and then may, or may not, be laser-marked (Step 214). Laser marking involves creating an alphanumeric identification mark on the wafer. The ID mark may identify the wafer manufacturer, flatness, conductivity type, wafer number and the like. The laser marking preferably is performed to a sufficient depth so that the ID mark remains even after portions of the wafer have been removed by subsequent process steps such as grinding, etching, polishing, and the like.

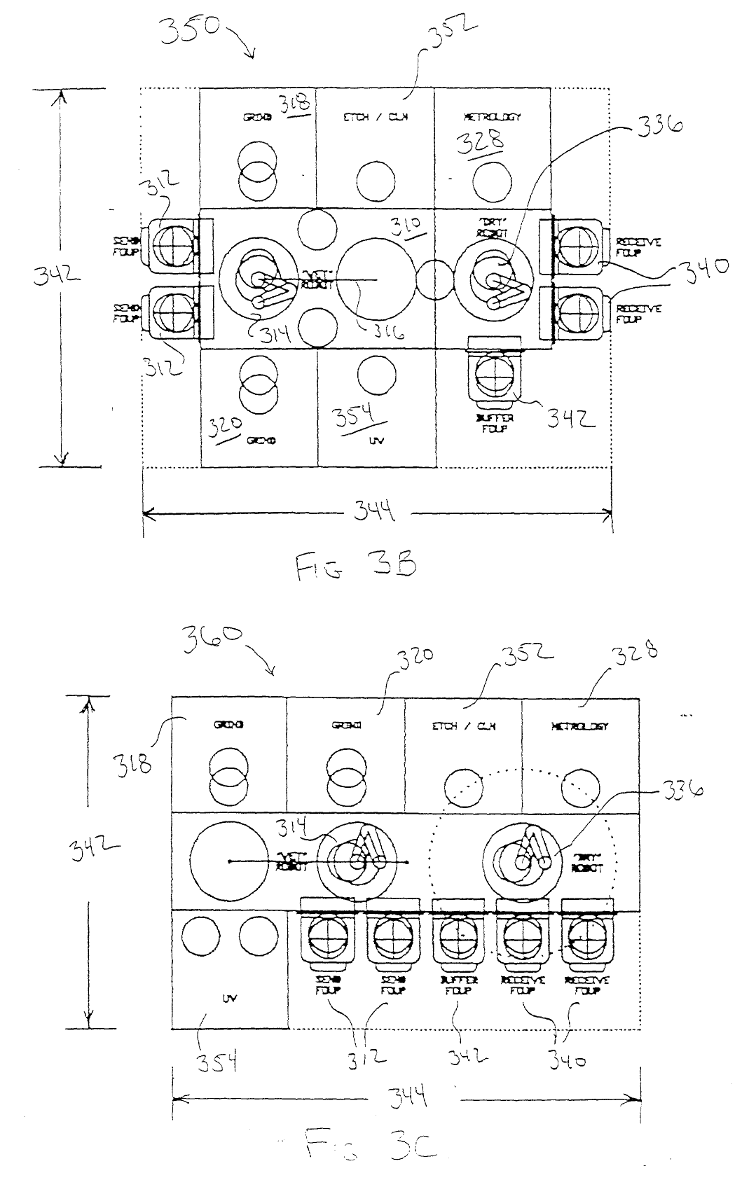

Thereafter, the wafer is processed through a first module (Step 216), with details of embodiments of the first module described below in conjunction with FIGS. 3A-3C. First module processing (Step 216) includes a grinding process, an etching process, a cleaning process and metrology testing of the wafer. In this module, the use of a grinding process in lieu of lapping helps to remove wafer bow and warpage. The grinding process of the present invention also is beneficial in removing wafer surface waves caused by the wafer slicing in Step 210. Benefits of grinding in lieu of lapping include reduced kerf loss, better thickness tolerance, improved wafer shape for polishing and better laser mark dot depth tolerance, and reduced damage, among others.

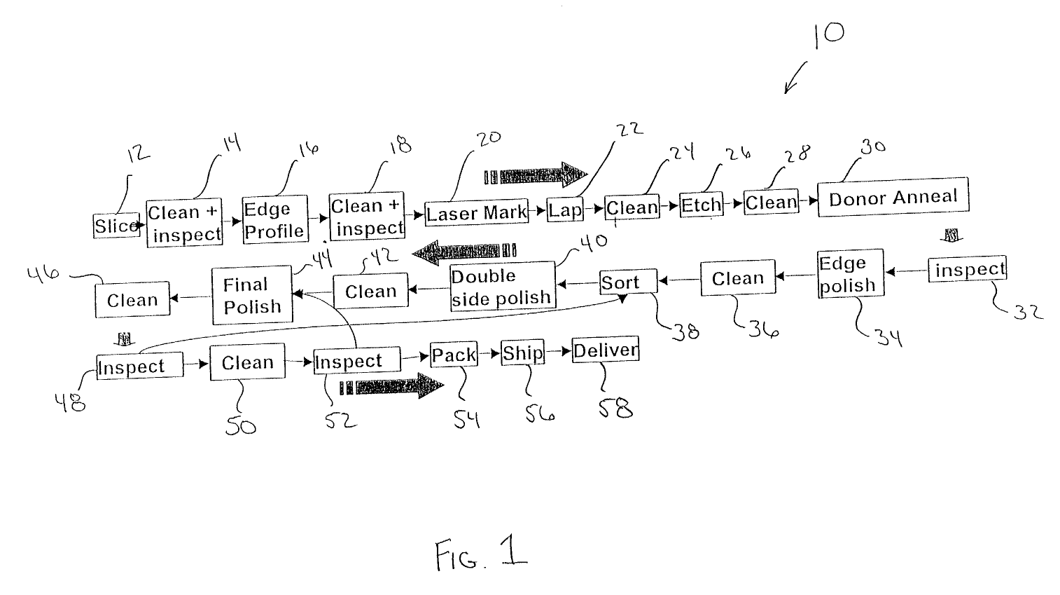

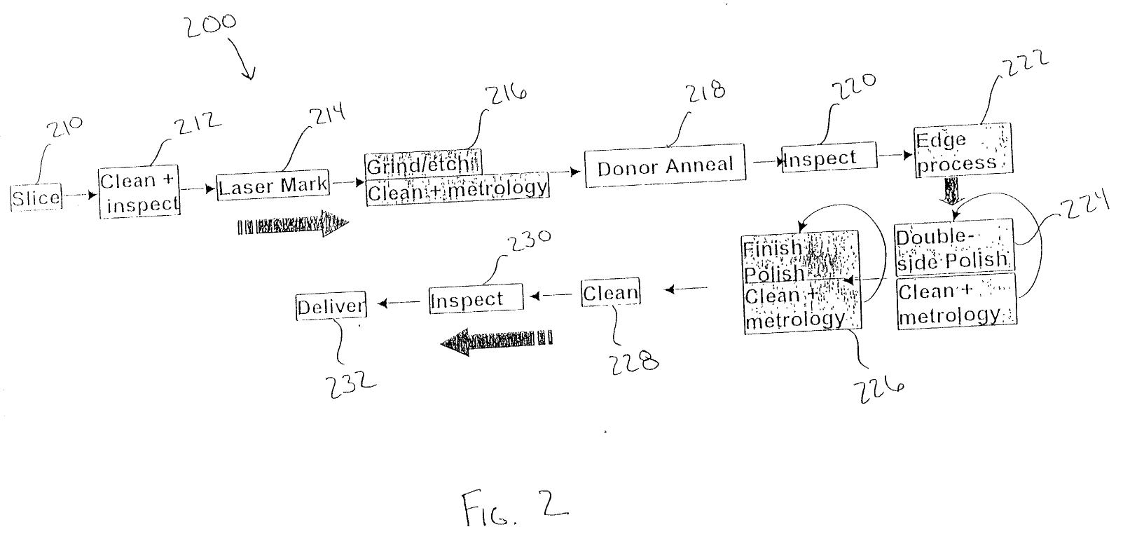

The grinding process within the first module is a more benign process than the prior art grind or lap step described in conjunction with FIG. 1. For example, conventional grinding may involve deep scratches forming a grind pattern in the wafer. The depth of such scratches cannot be lowered below ten (10) microns even with the use of a very fine abrasive, such as a 2000# diamond wheel in a vitrified matrix. To remove these scratches, considerable polish time and loss of significant wafer material is required. In contrast, the grind process of the present invention preferably leaves scratches of about six (6) microns or less in depth. Thus, the subsequent polish process can be performed in roughly 50% of the time required for a similar polish associated with a conventional grind. Furthermore, the grind process of the present invention reduces the amount of wafer material which must be removed during polish by approximately 50%.

Similarly, the etching process within the first module is a more benign process than the prior art etch step described in conjunction with FIG. 1. For example, typical prior art etching (Step 26 in FIG. 1) may involve the bulk removal of forty (40) or more microns of wafer thickness. In contrast, the etch process of the present invention preferably removes ten (10) microns or less from the wafer thickness. In one embodiment, the first module etch process removes between about two (2) microns to about five (5) microns of wafer material per side, or a total of about four (4) to about ten (10) microns. In another embodiment, the first module etch process removes between about three (3) microns and about four (4) microns of wafer material per side for a total of about six (6) to about (8) microns.

After first module processing, the wafer is subjected to a donor anneal (Step 218) and thereafter inspected (Step 220). The donor anneal removes unstable oxygen impurities within the wafer. As a result, the original wafer resistivity may be fixed. In an alternative embodiment, donor anneal is not performed.

The wafer then is processed through a second module (Step 222) in which an edge process is performed. The edge process includes both an edge profile and an edge polish procedure. Edge profiling may include removing chips from the wafer edge, controlling the diameter of the wafer and/or the creation of a beveled edge. Edge profiling also may involve notching the wafer to create primary and secondary flat edges. The flats facilitate wafer alignment in subsequent processing steps and/or provide desired wafer information (e.g., conductivity type). In one embodiment, one or both flats are formed near the ID mark previously created in the wafer surface. One advantage of the present invention involves performing the edge profiling after wafer grinding. In this manner, chips or other defects to the wafer edge, which may arise during grinding or lapping, are more likely to be removed. Prior art edge profiling occurs before lapping, and edge polishing subsequent to the lapping step may not sufficiently remove edge defects.

The wafer is then processed through a third module (Step 224). A third module process includes a double side polish, a cleaning process and wafer metrology. Wafer polishing is designed to remove stress within the wafer and smooth any remaining roughness. The polishing also helps eliminate haze and light point defects (LPD) within the wafer, and produces a flatter, smoother finish wafer. As shown by the arrow in FIG. 2, wafer metrology may be used to adjust the double side polishing process within the third module. In other words, wafer metrology may be feed back to the double side polisher and used to adjust the DSP device in the event the processed wafer needs to have different or improved characteristics, such as flatness, or to further polish out scratches.

Thereafter, the wafer is subjected to a finish polish, a cleaning process and metrology testing, all within a fourth process module (226). The wafer is cleaned (Step 228), inspected (Step 230) and delivered (Step 232).

With reference to FIGS. 3-9, additional details on process modules according to the present invention will be provided. It will be appreciated by those skilled in the art that the process modules described in FIGS. 3-9 are embodiments of the present invention, from which a large number of variations for each module exist within the scope of the present invention. Further, additional process steps may be removed or added, and process steps may be rearranged within the scope of the present invention.

FIG. 3A depicts a grind damage cluster module described as first module 216 in conjunction with FIG. 2. First module 300 defines a clean room environment 310 in which a series of process steps are carried out. Wafers that have been processed through Step 214 (FIG. 2) are received in first module 300 via a portal, such as a front opening unified pod (FOUP) 312. First module 300 is shown with two FOUPs 312, although a larger or smaller number of FOUPs/portals may be used. FOUPs 312 are adapted to hold a number of wafers so that the frequency of ingress into the clean room environment 310 may be minimized. A transfer device 314, schematically depicted as a robot, operates to remove a wafer from FOUPs 312 and place the wafer on a grinder 318. If needed, transfer device 314 travels down a track 316 to properly align itself, and hence the wafer, in front of grinder 318. Grinder 318 operates to grind a first side of the wafer.

The wafer may be held down on grinder 318 by way of a vacuum or other type of chuck, and other methods. Once grinder 318 has ground the first side of the wafer, the wafer is cleaned in cleaner 322 and the transfer device 314 transfers the wafer back to grinder 318 for grinding the converse side of the wafer. In one embodiment, wafer grinding of both wafer sides removes about forty (40) microns to about seventy (70) microns of wafer thickness. After the second wafer side is ground, the wafer is again cleaned in cleaner 322. In one embodiment, cleaning steps occur on grinder 318 subsequent to grinding thereon. In one embodiment, cleaning and drying are accomplished by spraying a cleaning solution on the wafer held by or near the edges and spun.

In another embodiment, at least one side of the wafer is subjected to two sequential grinding steps on grinder 318. The two grinding processes preferably include a coarse grind followed by a fine grind. Grinder 318 may include, for example, two different grinding platens or pads with different grit patterns or surface roughness. In one embodiment, the wafer is cleaned on grinder 318 between the two grinding steps to the same wafer side. Alternatively, cleaning may occur after both grinding steps to the same wafer side.

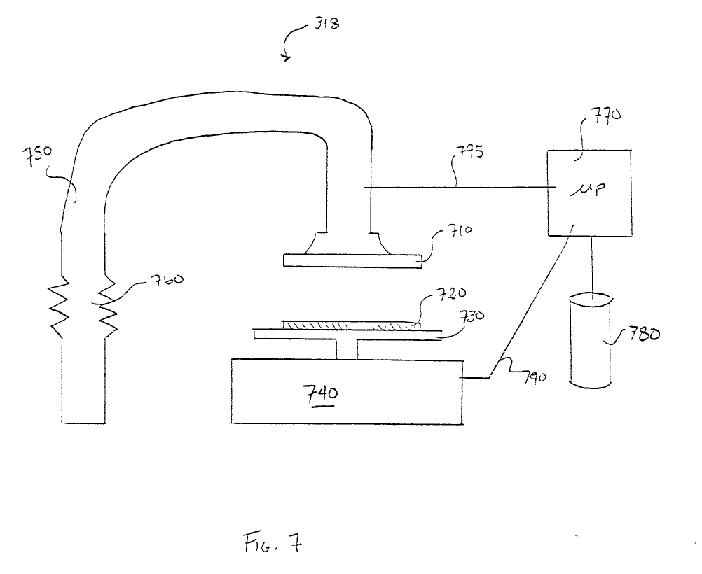

A schematic side view of grinder 318 is illustrated in FIG. 7. Referring to FIG. 7, a wafer 720 is attached to a chuck 730 with a wafer back 722 affixed to chuck 730. Chuck 730 is attached to a grinder base 740. A wafer face 724 is located relative to a grinding element 710, which is attached to grinder 318. In some embodiments, grinding element 710 is a grinding wheel with diamond abrasive imbedded therein. In one embodiment, contact between grinding element 710 and wafer 720 is caused by adjusting the height of a grinder arm 750 using a height adjustment 760.

In addition, a microprocessor based controller 770 provides commands to grinder 318, including to chuck 730 across interfaces 790 and 795. Such commands are derived from computer executable code resident on database 780. The commands can include control of rotational velocity of grinding element 710 and/or chuck 730, as well as control of height adjustment 760.

Grinder 318 removes material from wafer 720 by contacting grinding element 710 with wafer 720 as wafer 720 and grinding element 710 are rotated relative to each other. The rotation of grinding element 710 relative to wafer 720 occurs at a rotational velocity. In some embodiments, providing this relative rotation is done by rotating grinding element 710, while maintaining chuck 730, and thereby wafer 720 in a generally fixed position. Thus, in this embodiment, the rotational velocity is the velocity of grinding element 710. In other embodiments, providing the relative rotation is done by rotating chuck 730, and thereby wafer 720, while maintaining grinding element 710 in a fixed position. Therefore, the rotational velocity is the speed at which chuck 730 is rotating wafer 720. In yet other embodiments, the relative rotation is provided by rotating both grinding element 710 and chuck 730. In such embodiments, the rotational velocity is the difference between the speed at which grinding element 710 and chuck 730 are rotating.

In still another embodiment, wafer 720 is rotated relative to both chuck 730 and grinding element 710. For example, a rotational device (not shown) may be coupled to a template (not shown) in which wafer 720 resides, with the rotational device rotating the template, and hence wafer 720.

According to the present invention, the rotational velocity is varied during the wafer grind steps. Varying the rotational velocity allows for greater self dressing of grinder element 710 and ploughing at the early part of the grinding cycle. In particular, self dressing includes constantly exposing abrasive poritons of the grinding element and ploughing includes cutting into a work piece as opposed to a dull surface merely scratching the surface and generating frictional heat. Thus, the change in velocity regenerates the face of grinder element 710 to expose abrasive material imbedded therein. In some embodiments, the velocity of relative rotation is gradually increased over the duration of the grinding process. Thus, for example, rotational velocity may be increased from about forty (40) revolutions per minute (rpm) up to over about 700 rpm. By varying the rotational velocity, the resulting grind pattern depth incident on wafer 720 is both reduced and/or minimized in comparison to conventional grinding processes. Such a reduction of grind pattern depth is observable using post polish optical characterization methods, such as, ADE's Magic mirror or other interferometric methods.

As an example, the present invention is capable of reducing the depth of the grind pattern to less than ten (10) microns. In some embodiments of the present invention, the grind pattern may be reduced to about six (6) microns or less. Because of the reduced depth of grind patterns, material removal during subsequent polishing steps is reduced along with the time required to finish the polishing step. This results in more wafers per boule, increased wafer throughput, a reduction in flatness degradation and also a reduction in the incidence of rapid anisotropic etching during subsequent polish steps.

Other embodiments, which similarly reduce grind pattern depth involve gradually reducing the rotational velocity from about 700 rpm down to about 40 rpm. Yet other embodiments involve incrementally increasing or decreasing rotational velocity during the grinding process. For example, in one embodiment, the grinding process begins at a rotational velocity between approximately 40 and 250 rpm for a first period. The rotational velocity is then incrementally increased to a speed between approximately 250 and 450 rpm for a second period and the grind is finished by incrementing the rotational velocity to between approximately 450 and 700 rpm for a third period. In some embodiments, ten (10) microns of material is removed at two (2) microns per second during the first period, 5 (five) microns of material is removed at 0.5 microns per second during the second period, and 5 (five) microns of material is removed at 0.3 microns per second during the third period.

Additionally, varying the rotational velocity during the grinding process results in a distribution of stress across the crystal lattice of the wafer. Thus, the incidence of high stress points on the wafer are minimized. By minimizing high stress points on the wafer, the incidence of rapid anisotropic etching is further lowered and a more uniform polishing of the wafer under alkaline conditions (ph>7) is achieved.

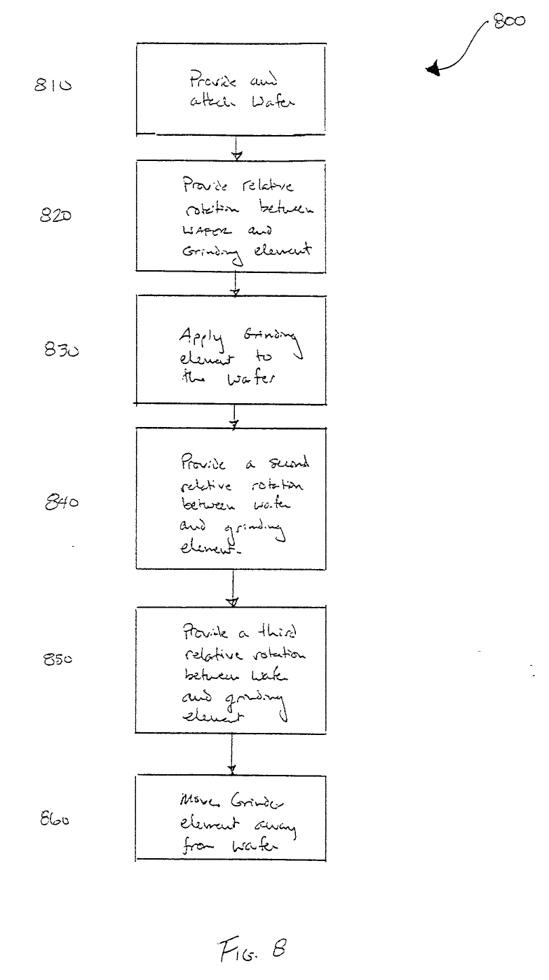

FIG. 8 illustrates a flow diagram 800 according to an embodiment of the present invention where the rotational velocity is varied during a grind of wafer 720. Referring to FIG. 8, wafer 720 is provided and wafer back 722 is coupled to chuck 730 (step 810). Grinding element 710 is rotated relative to wafer 720 (step 820). Grinding element 710 is brought into contact with wafer 720 by adjusting the height of grinder arm 750 using height adjustment 760 (step 830).

With grinder element 710 in contact with wafer 720, a grind is performed at a rotational velocity of between approximately 40 and 250 rpm. The rotational velocity is then incrementally increased to a speed between approximately 250 and 450 rpm (step 840). After a period, the rotational velocity is increased to between approximately 450 and 700 rpm (step 850). Once the grind is completed, grinding element 710 is moved away from wafer 720, again by adjusting the height of grinder arm 750 by articulating height adjustment 760 (step 860).

Other embodiments, which similarly reduce grind pattern depth involve gradually reducing the relative rotational velocity between grinder element 710 and wafer 720 from about 700 rpm to about 40 rpm. Yet other embodiments involve gradually increasing or decreasing the relative rotational velocity between grinder element 710 and wafer 720 during the grinding process. For example, in one embodiment, the grinding process begins at a rotational velocity of about 40 rpm and is ramped over a smooth velocity curve to a velocity of over 700 rpm.

Of course, it should be recognized by those skilled in the art that varying the relative rotational velocities between grinder element 710 and wafer 720 may be performed during one grind step and not performed during another. For example, varying the relative rotational velocity between grinder element 710 and wafer 720 may be done during a fine grind step, and not during the coarse grind. Additionally, it should be recognized that causing contact between wafer 720 and grinding element 710 can be accomplished by moving chuck 730 toward grinding element 710, rather than by moving grinding element 710.

In some embodiments, the grind pattern remaining after the grinding process described in relation to FIG. 7 is removed using an etch step according to the present invention. The etch removes a depth of wafer material approximately equal to the depth of the remaining grind pattern. Thus, in some embodiments, the etch step removes less than about seven (7) microns per wafer side, or less than about fourteen (14) microns from both of the wafer sides combined. In embodiments where the grind pattern depth is about six (6) microns, the etch step removes as little as about three (3) to about four (4) microns of wafer material from each side of the ground wafer. Therefore, in some embodiments, less than about eight (8) total microns of wafer material is removed during the etch step. This is compared to traditional etch steps which involve removal of twenty-five (25) microns of wafer material or more.

Because the present invention removes such a minimal amount of material compared to conventional etch steps, shape degradation of the wafer is advantageously reduced or minimized. This reduction in shape degradation is particularly pronounced around the edges of the wafer where the surface area exposed to the etchant is greatest. By protecting the edges from significant etch damage, subsequent edge polishing steps can be reduced or even eliminated. Further, by reducing shape degradation, wafers with improved flatness (e.g., measured TTV or STIR) can be produced.

Some embodiments of the etch according to the present invention rely on an acid etchant. In one embodiment, the acid etchant comprises HNO₃, HF and a diluent. I The diluent can be, for example, CH₃COOH. In an embodiment, the ratio is about 1:0.2:0.5 of HNO₃, HF and CH₃COOH, respectively. This acid media serves not only to remove the grind pattern incident from a preceding grind step, but also serves to leach out metal contamination introduced during preceding fabrication steps. Such metal contamination can include copper (Cu) and/or iron (Fe), as well as other metals. Thus, the etching step according to the present invention also serves as a cleaning step and reduces or eliminates the need for further cleaning of wafers after the etching step is performed.

In an embodiment where a single crystal silicon wafer is etched, grind pattern depth is approximately six (6) microns and the acid etchant comprises HNO₃+HF, the etch is performed for approximately three (3) to five (5) minutes.

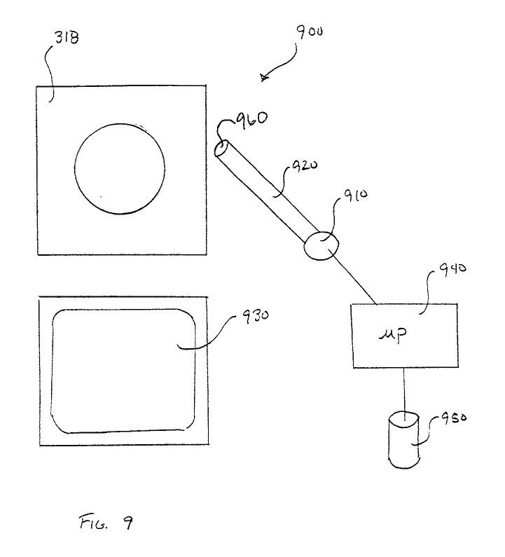

FIG. 9 illustrates, in simplified schematic form, a combined etch and grinding apparatus 900. Apparatus 900 includes grinder 318, an etchant bath 930, and a wafer transfer arm 920. Wafer transfer arm 920 includes a pivot 910 which allows the arm to move and a susceptor 960 capable of holding wafer 720 while it is moved from grinder 318 to etchant bath 930, and then from etchant bath 930 to subsequent processing machines. A microprocessor base controller 940 controls operation of wafer transfer arm 920 based on computer executable code resident on a database 950.

In operation, a grind is performed on a wafer by grinder 318. Upon completion of the grind, wafer transfer arm 920 is moved under direction of microprocessor based controller 940 until it is near wafer 720. Susceptor 960 then couples to wafer 720, such as by lifting wafer 720, and wafer transfer arm 920 is moved towards etchant bath 930. Susceptor 960 then releases the wafer into etchant bath 930 where the etch process is performed. In a particular embodiment, arm 920 and susceptor 960 comprise a robot. Upon completion of the etch process, the wafer is removed from etchant bath 930 and made available for further processing steps. Thus, each wafer is individually etched by a system including an integrated grinder and etcher.

A combination of the grinding step, where the grind pattern depth is less than about ten (10) microns deep, and the subsequent etch step according to the present invention advantageously eliminates the need for lapping, cleaning and caustic etch steps of the conventional technology. By eliminating these conventional steps, and co-locating the systems used to perform the grind and etch steps according to the present invention, efficient wafer processing is facilitated. Further, the need to pre-clean wafers prior to thermal annealing and/or form thin film getters, such as, polysilicon or low thermal oxide layers is reduced or eliminated. Thus, in addition to other advantages, manufacturing costs are reduced and the amount of manufacturing space, and thus, facility investment costs are reduced.

Returning to FIG. 3A, in some embodiments, transfer device 314 transfers the wafer from cleaner 322 to a backside polisher 326. For example, this process flow may occur for 200 mm wafers. In this embodiment, the back side is polished and not ground, or both ground and polished.

As shown in FIG. 3A, a second grinder 320 and a second cleaner 324 are provided within module 300. In this manner, two wafers may be simultaneously processed therethrough. Since both grinders 318, 320 have a corresponding cleaner 322, 324, wafer processing times are consistent even if two wafers are being ground simultaneously on grinders 318, 320. In one embodiment, grinders 318 and 320 are used to grind opposite sides of the same wafer. In this case, one side of the wafer is ground on grinder 318 and the other side of the same wafer is ground on grinder 320. As with grinder 318, wafers may be ground on grinder 320 and then cleaned on grinder 320 before removal, or cleaned in cleaner 324.

Once the wafers have been ground, a second transfer device 336, again a robot in one embodiment, operates to transfer the wafer to an etcher 330. Etcher 330 operates to remove material from the wafer, preferably a portion on both primary sides of the wafer. The etching process is designed to remove stresses within the silicon crystal caused by the grinding process. Such an operation, in one embodiment, removes ten (10) microns or less of total wafer thickness. In this manner, etcher 330 operates to remove less wafer material than in prior art etch processes. Further, the present invention requires less etchant solution, and hence poses fewer environmental problems related to disposal of the acids or other etchants.

Wafer metrology is then tested at a metrology station 328. In one embodiment wafer metrology is tested subsequent to grinding on grinder 318, and prior to the etching within etcher 330. Alternatively, wafer metrology is tested subsequent to etching in etcher 330. In still another embodiment, wafer metrology is tested both prior to and subsequent to the etching process. Evaluation of wafer metrology involves the testing of wafer flatness and other wafer characteristics to ensure the wafer conforms to the desired specifications. If the wafer does not meet specifications, the wafer is placed in a recycle area 342, which in one embodiment comprises a FOUP 342 (not shown in FIG. 3A). Wafers with acceptable specifications are placed in an out portal or FOUP 340 for removal from first module 300.

As shown and described in conjunction with FIG. 3A, first module 300 provides an enclosed clean room environment in which a series of process steps are performed. Wafers are processed in series through first module 300. Hence, each wafer has generally uniform or uniform process time through the module as well as generally uniform or uniform delay times between process steps. Further, by immediately cleaning and etching the wafer after grinding, the formation of haze and light point defects (LPD) within the wafer are reduced. Such a module configuration is an improvement over the prior art in which wafers are typically processed during the lapping step in batch mode. As a result, some wafers will wait longer before the cleaning or etching steps than others within the same batch. As a result, haze and other wafer defects vary from wafer to wafer, even between wafers within the same batch. Such a shortcoming of the prior art can make it difficult if not impossible to isolate problems within the wafer process flow in the event defective wafers are discovered.

An additional benefit of first module 300 is its compact size. In one embodiment, module 300 has a width 342 that is about 9 feet 3 inches and a length 344 that is about 12 feet 6 inches. In another embodiment, first module 300 has a footprint ranging between about ninety (90) square feet (sqft) and about one hundred and fifty (150) square feet. It will be appreciated by those skilled in the art that the width and length, and hence the footprint of first module 300, may vary within the scope of the present invention. For example, additional grinders 318, 320 may be added within first module 300 to increase the footprint of module 300. In one embodiment, first module 300 is adapted to process about thirty (30) wafers per hour. In another embodiment, first module 300 is adapted to process between about twenty-nine (29) and about thirty-three (33) 300 mm wafers per hour.

FIG. 3B depicts an alternative embodiment of a grind damage cluster module according to the present invention. Again, the grind damage cluster module 350 may correspond to first module 216 described in conjunction with FIG. 2. Module 350 includes many of the same components as the embodiment depicted in FIG. 3A, and like reference numerals are used to identify like components. Module 350 receives wafers or substrates to be processed at portal 312, identified as a send FOUP 312 in FIG. 3B. Wafers are transferred by transfer device 314, shown as wet robot 314, to a preprocessing station 354. In one embodiment, transfer device 314 travels on a track, groove, raised member or other mechanism which allows transfer device 314 to reach several process stations within module 350.

At preprocessing station 354, a coating is applied to one side of the wafer. In one embodiment, a polymer coating is spun on the wafer to provide exemplary coverage. This coating then is cured using ultraviolet (UV) light to provide a low shrink, rapid cured coating on one side of the wafer. In addition to UV curing, curing of the coating may be accomplished by heating and the like. In a particular embodiment, the coating is applied to a thickness between about five (5) microns and about thirty (30) microns.

Once cured, the coating provides a completely or substantially tack free, stress free surface on one side of the wafer. In one embodiment of the present invention, transfer device 314 transfers the wafer to grinder 318, placing the polymer-coated side down on the grinder 318 platen. In one embodiment, the platen is a porous ceramic chuck which uses a vacuum to hold the wafer in place during grinding. The waves created during wafer slicing are absorbed by the coating and not reflected to the front side of the wafer when held down during the grinding process. After the first wafer side is ground on grinder 318, the wafer is flipped over and the second side is ground. As described in conjunction with FIG. 3A, an in situ clean of the wafer may occur before turning the wafer, or the wafer may be cleaned subsequent to grinding of both sides. Again, the second side grinding may occur on grinder 318 or grinder 320. Grinding of the second side removes the cured polymer, and a portion of the second wafer surface resulting in a generally smooth wafer on both sides, with little to no residual surface waves. Additional details on exemplary grinding methods are discussed in U.S. patent application Ser. No. ______ (Attorney Docket No. 20468-001010), entitled “Cluster Tool Systems and Methods To Eliminate Wafer Waviness During Grinding,” the complete disclosure of which is incorporated herein by reference.

After grinding on grinder 318 and/or 320, the wafer is transferred to a combined etch/clean station 352 for wafer etch. Again, wafer etching in station 352 removes a smaller amount of wafer material, and hence requires a smaller amount of etchant solutions, than is typically required by prior art processes.

Processing continues through module 350 ostensibly as described in FIG. 3A. The wafer metrology is tested at metrology station 328. Wafers having desired characteristics are transferred by transfer device 336, shown as a dry robot, to out portals 340, identified as receive FOUPS 340 in FIG. 3B. Wafers having some shortcoming or undesirable parameter are placed in a recycle area 342, shown as a buffer FOUP 342, for appropriate disposal.

In one embodiment, module 350 has a width 342 at its widest point of about one hundred and fourteen (114) inches, and a length at its longest point of about one hundred and forty-five inches (145), with a total footprint of about one hundred and fourteen square feet (114 sqft). As will be appreciated by those skilled in the art, the dimensions and footprint of module 350 may vary within the scope of the present invention.

Still another embodiment of a grind damage cluster module according to the present invention is shown in FIG. 3C. FIG. 3C depicts a first module 360 having similar stations and components as module 350 described in FIG. 3B. However, module 350 is a flow through module, with wafers being received at one end or side of module 350 and exiting an opposite end or side of module 350. Module 360 has FOUPS 312, 342 and 340 grouped together. Such a configuration provides a single entry point into module 360, and hence into clean room environment 310. Transfer devices 314 and 336 again facilitate the movement of wafers from station to station within module 360. As shown in FIGS. 3B and 3C, transfer device 314 travels on mechanism 316, as discussed in conjunction with FIG. 3B. Transfer device 336 operates from a generally fixed position with arms or platens extending therefrom to translate the wafer to the desired processing station. Module 360 further includes station 354 for application of a wafer coating, such as the UV cured polymer coating described above.

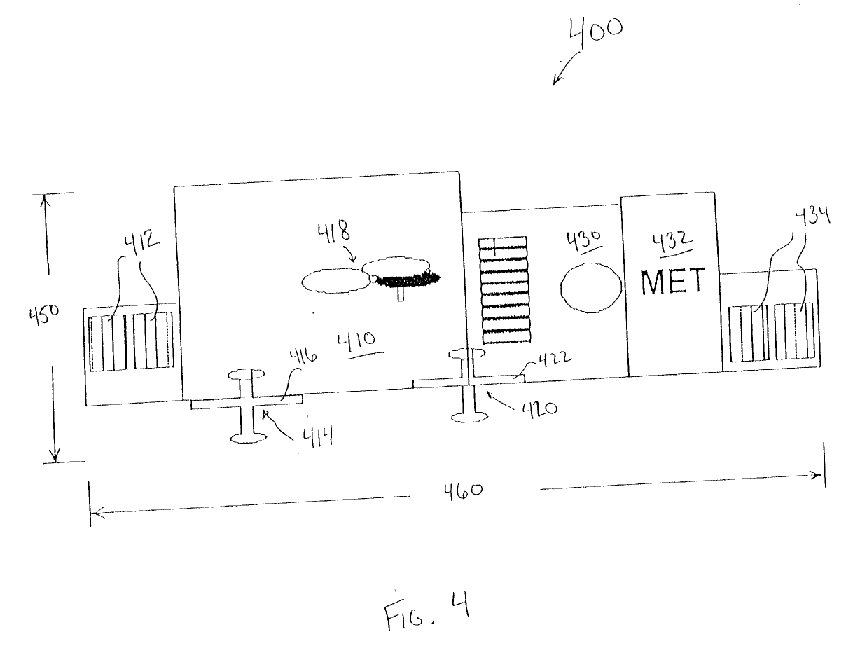

Turning now to FIG. 4, an exemplary second module comprising an edge profile and edge polishing module will be described. Second module 400 again includes a clean room environment 410 to facilitate clean operations. Second module 400 has a portal 412 for receiving wafers to be processed. Again, in one embodiment, portal 412 is one or more FOUPs. A robot or other transfer device 414 operates to take a wafer from portal 412 and transfer the wafer to an edge profiler/polisher 418. Edge profiler/polisher 418 may comprise one device, or two separate devices with the first device for profiling and the second device for polishing. Transfer device 414 may travel down a track 416 to permit proper placement of the wafer in the edge profiler/polisher 418.

The edge of the wafer is profiled and polished as described in conjunction with FIG. 2. In one embodiment, edge profiling removes about ten (10) microns to about fifty (50) microns of material from the diameter of the wafer, with a resultant diameter tolerance of about +/−0.5 μ. After edge profiling and polishing, a transfer device 420 operates to transfer the wafer to a cleaner 430. Again, transfer device 420 may travel on a track 422 to place the wafer in cleaner 430. Cleaner 430 may comprise a mixture of dilute ammonia, peroxide, and water, or an ammonia peroxide solution and soap, followed by an aqueous clean, and the like.

Subsequent to cleaning in cleaner 430, the wafer is transferred to a metrology station 432 at which wafer metrology is examined. An out-portal 434 is positioned to receive wafers having successfully completed processing through second module 400. In one embodiment, portal 434 is a FOUP which collects wafers meeting desired specifications. Again, rejected wafers are set aside in a separate area or FOUP.

Second module 400 has a compact configuration similar to first module. In one embodiment, second module 400 has a width 450 of about 7 feet 6 inches and a length 460 of about 22 feet 11 inches. In another embodiment, second module 400 has a footprint ranging between about ninety (90) square feet (sqft) and about one hundred and fifty (150) square feet. The module 400 shown in FIG. 4 may be used to carry out process step 222 depicted in FIG. 2. In one embodiment, second module 400 processes about thirty (30) wafers per hour. In another embodiment, second module 400 is adapted to process between about twenty-nine (29) and about thirty-three (33) 300 mm wafers per hour. In still another embodiment, second module 400 processing occurs prior to first module 300 processing. In this manner, edge profile and/or edge polish procedures occur before wafer grinding.

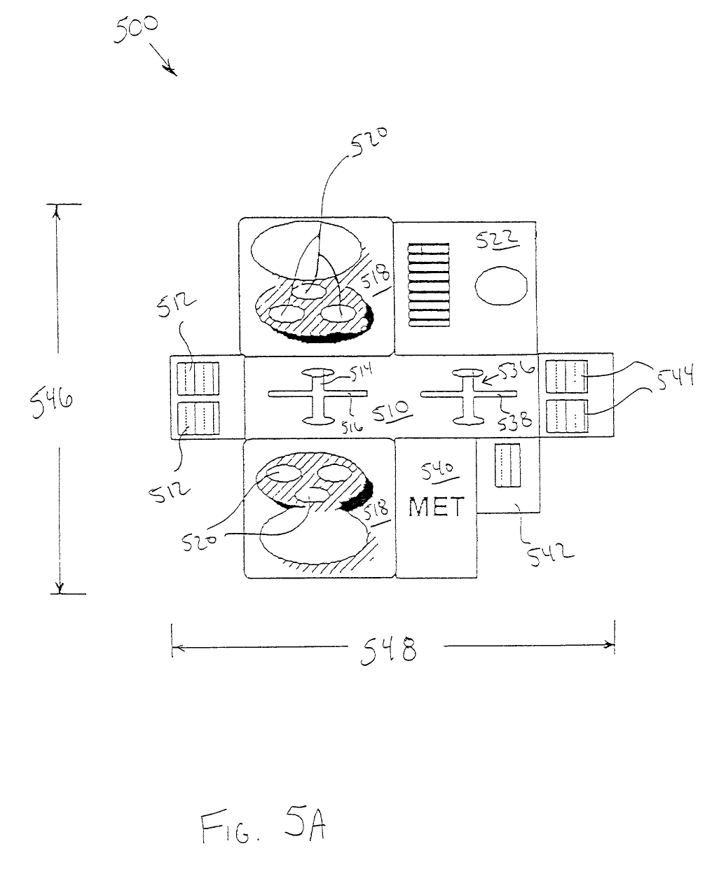

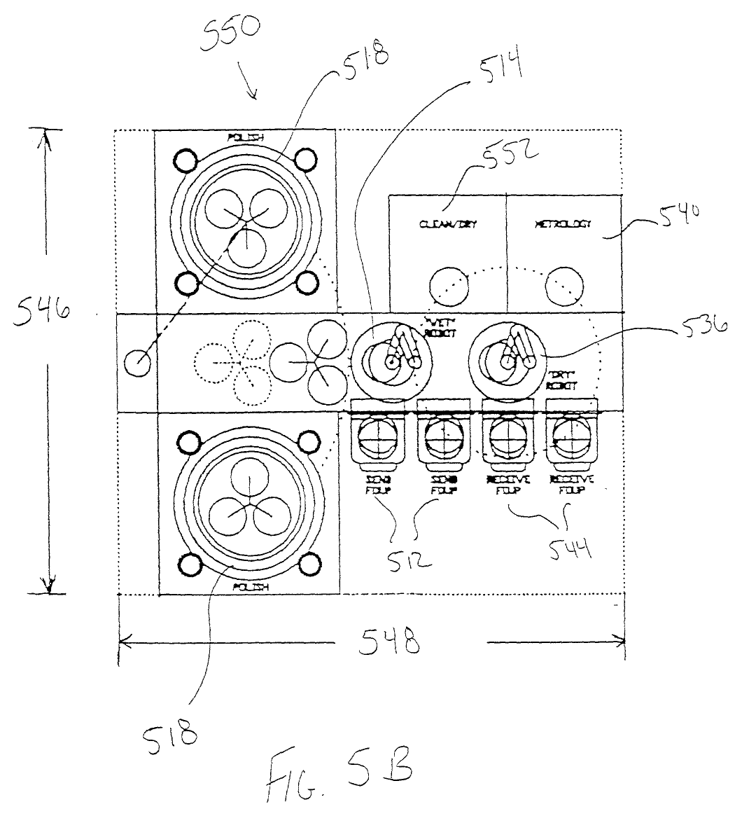

FIG. 5A depicts a third module 500 comprising a double side polisher for use in process step 224 shown in FIG. 2. Module 500 again includes an in-portal 512 which may be one or more FOUPs in one embodiment. Wafers are received in portal 512 and transferred within a clean room environment 510 by a transfer device 514. Transfer device 514, which in one embodiment is a robot, may travel along a track 516 to deliver the wafer to one or more double side polishers (DSP) 518.

As shown in FIG. 5A, double side polisher 518 accommodates three wafers 520 within each polisher. It will be appreciated by those skilled in the art that a greater or fewer number of wafers may be simultaneously polished within DSP 518. Prior art double side polishing (DSP) typically polishes a batch of ten or more wafers at a time in a double side polisher. The polisher initially only contacts the two or three thickest wafers due to their increased height within the DSP machine. Only after the upper layers of the thickest wafers are removed by polishing, are additional wafers polished within the batch. As a result, the batch mode polishing takes longer, and uses more polishing fluids and deionized water than in the present invention.

Hence in one preferred embodiment of the present invention, three wafers are polished simultaneously. Subsequent to polishing on polisher 518, the wafers are transferred via a transfer device 536, traveling on track 538 to a buffer station 522. Thereafter, the wafers are buffed, cleaned and dried. Either prior to or after processing through station 522, or both, wafers are tested at a metrology station 540. For wafers meeting desired specifications, transfer device 536 transfers those wafers to an out-portal 544, again, one or more FOUPs in one embodiment. Wafers which do not meet specifications are placed in a reject FOUP 542.

As with prior modules, the third module 500 has a compact footprint. In one embodiment, module 500 has a width 546 that is about 13 feet 11 inches and a length 548 that is about 15 feet 11 inches. In another embodiment, third module 500 has a footprint ranging between about one hundred (100) square feet (sqft) and about one hundred and eighty (180) square feet. Third module 500 may have a different footprint within the scope of the present invention.

In one embodiment, DSP 518 removes about twelve (12) microns of wafer thickness from both sides combined, at a rate of about 1.25 to 2.0 microns per minute. DSP 518 operates on a twelve (12) minute cycle time per load. Hence, in one embodiment, two DSPs 518 process about thirty (30) wafers per hour. In another embodiment, third module 500 is adapted to process between about twenty-nine (29) and about thirty-three (33) 300 mm wafers per hour. It will be appreciated by those skilled in the art that DSP 518 process times, third module 500 throughput, and other parameters may vary within the scope of the present invention. For example, additional DSPs 518 may be added to increase module 500 throughput. In one embodiment, wafer metrology tested at metrology station 540 is fed back to DSPs 518 to adjust DSP 518 operation as needed to produce desired wafer metrology.

FIG. 5B depicts an alternative embodiment of a third module according to the present invention. As shown in FIG. 5B, third module 550 comprises a double side polisher for use in process step 224 shown in FIG. 2, as well as several other components shown in FIG. 5A. As a result, like components are identified with like reference numerals. Module 550 includes a clean/dry station 552 for wafer cleaning and drying subsequent to wafer polishing in polisher 518. Transfer devices 514 and 536, shown as a wet robot and a dry robot, respectively, operate to transfer wafers within module 550. In one embodiment, transfer device 514 travels on a track, groove, raised feature or the like to reach several processing stations and portals 512, while transfer device 536 operates from a fixed base.

While module 500 in FIG. 5A is a flow through module, with wafers received by module 500 at one side and exiting from an opposite side, module 550 in FIG. 5B groups portals 512 and 544. Again, such a grouping of in and out portals facilitates access to module 550 from a single point or side. In one embodiment, a buffer or reject FOUPS (not shown) also is grouped with portals 512 and 544. Alternatively, one or more of portals 512 and 544 may operate as a reject FOUPS.

Third module 550, in one embodiment, has a compact footprint with a width 546 at the widest point of about one hundred and forty two (142) inches and a length at the longest point of about one hundred and fifty-five inches (155).

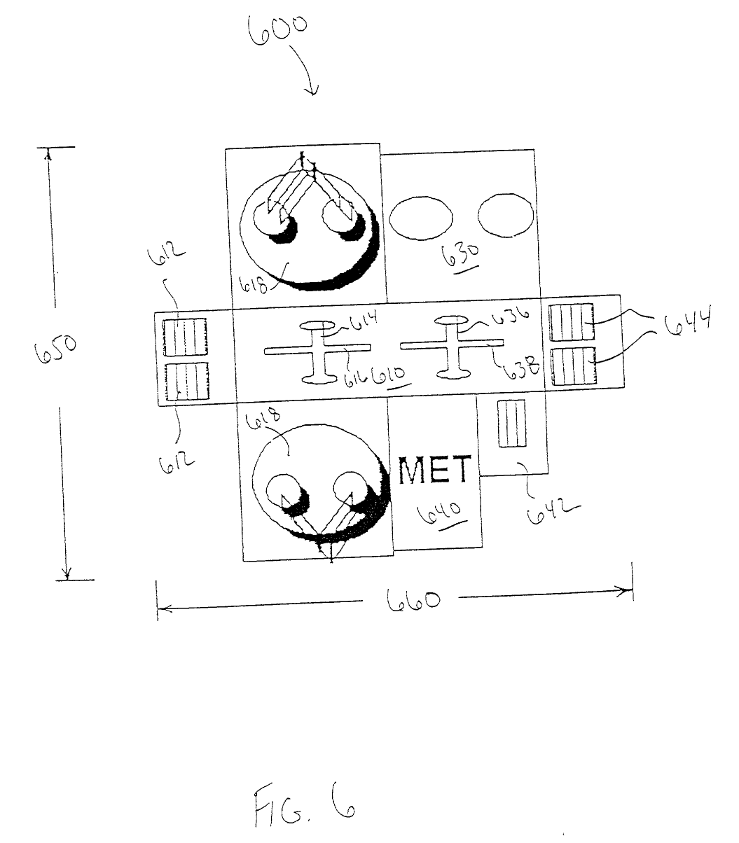

Turning now to FIG. 6, a fourth module 600, comprising a finish polish cluster, will be described. Fourth module 600 in one embodiment will be used for process step 226 shown in FIG. 2. As with the prior modules, fourth module 600 defines a clean room environment 610 which has ingress and egress through one or more portals or FOUPs. For example, an in-portal or FOUP 612 receives a plurality of wafers for finish polishing. Wafers are removed from FOUP 612 and transferred by a transfer device 614 along a track 616 to a finish polisher 618. While two finish polishers 618 are depicted in FIG. 6, a larger or smaller number of polishers 618 may be used within the scope of the present invention.

Wafers are finish polished for about five (5) to six (6) minutes within finish polisher 618 in an embodiment. Wafers that have undergone finish polishing are transferred to a single wafer cleaner 630 by a transfer device 636. Again, transfer device 636 in one embodiment comprises a robot that travels along a track 638. After wafer cleaning at cleaner station 630, wafer metrology is again tested at a metrology station 640. In one embodiment, metrology processing within fourth module 600 uses a feedback loop to provide data to finish polishers 618 as a result of wafer metrology testing. In one embodiment, the feedback loop is of sufficiently short duration to permit adjustments to the finish polisher process prior to the polishing of the next wafer after the wafer being tested. Wafers which do not meet specification are placed in a reject FOUP or portal 642 for proper disposal. Wafers meeting specifications will be placed in an out-portal or FOUP 644 for subsequent processing, packaging and shipping.

Fourth module 600, in one embodiment, has a width 650 of about 14 feet 0 inches and a length 660 of about 16 feet 0 inches. In another embodiment, fourth module 600 has a footprint ranging between about one hundred (100) square feet (sqft) and about one hundred and eighty (180) square feet. Again, as with all prior modules, the exact size may vary within the scope of the present invention. In one embodiment, fourth module 600 processes about thirty (30) wafers per hour. In another embodiment, fourth module 600 is adapted to process between about twenty-nine (29) and about thirty-three (33) 300 mm wafers per hour.

In one embodiment, the four modules 300, 400, 500 and 600, or their alternative embodiments, and ancillary equipment take up about 4,000 square feet or less of a production facility. This total footprint is much smaller than required for prior art equipment performing similar processes. As a result, apparatus, systems and methods of the present invention may be incorporated more readily in smaller facilities, or as part of a device fabrication facility in which circuit devices are formed. In this manner, the time and cost of packing and shipping, as well as unpacking and inspecting, are avoided. The costs of packing and shipping can, for example, save on the order of about two (2) percent or more of the total wafer processing costs. Additional details on exemplary in-fab wafer processing methods are discussed in U.S. patent application Ser. No. ______ (Attorney Docket No. 20468-000310), entitled “Cluster Tool Systems and Methods for In Fab Wafer Processing”, the complete disclosure of which is incorporated herein by reference.

The invention has now been described in detail for purposes of clarity and understanding. However, it will be appreciated that certain changes and modifications may be practiced within the scope of the appended claims. For example, the modules may have different layouts, dimensions and footprints than as described above. Additionally, transfer devices that have been described as traveling or fixed, may also be fixed or traveling, respectively.

What is claimed is:

1. A method of grinding wafers for use in manufacturing circuit devices, the method comprising:
providing a wafer having a front, a back, and an edge;
grinding the wafer, wherein said grinding forms a grind pattern on the front of the wafer having a depth of ten microns or less;
etching the ground wafer using an etchant, wherein less than approximately twenty microns of wafer material is removed from a combination of the front and the back of the wafer, and wherein metallic contamination of the wafer is substantially removed by the etchant.

2. The method of claim 1, wherein the etchant comprises an acid.

3. The method of claim 2, wherein the acid comprises HF.

4. The method of claim 3, wherein the acid further comprises HNO₃.

5. The method of claim 1, wherein the grind pattern on the front of the wafer has a depth of seven microns or less, and wherein etching the ground wafer removes less than fourteen microns of wafer material from a combination of the front and the back side of the wafer.

6. The method of claim 5, wherein said grinding and said etching substantially removes said grind pattern from said front.

7. The method of claim 1, wherein the wafer is 200 millimeters or larger and wherein said etching comprises immersing the wafer in an etchant bath, the method further comprising:
removing the wafer from the etchant bath, wherein a total thickness variation (TTV) of the wafer after removal from the etchant bath is between about 0.3 microns and about 0.5 microns.

8. The method of claim 1, wherein the wafer is 300 millimeters or larger and wherein said etching comprises immersing the wafer in an etchant bath, the method further comprising:
removing the wafer from the etchant bath, wherein the TTV of the wafer after removal from the etchant bath is between about 0.4 microns and about 0.7 microns.

9. The method of claim 1, wherein grinding the wafer comprise grinding at a first grind speed and subsequently grinding at a second grind speed.

10. The method of claim 1, wherein the grinding the wafer comprises grinding at a variable speed, wherein the variable speed is gradually increased over the course of said grinding.

11. The method of claim 1, wherein the grinding comprises a first coarse grind followed by a subsequent fine grind.

12. A system for providing wafers which are substantially free of metal contamination without requiring a separate cleaning step, the system comprising:
a wafer having a wafer face;
a grinder, wherein the grinder is adapted to flatten the wafer face while leaving a grind pattern in the face having a depth that is less than ten microns;
an etchant bath integrated with the grinder, said etchant bath adapted to chemically solubolize the wafer material wherein metal contamination is removed from the wafer; and
a transfer mechanism for moving said wafer from said grinder to the etchant bath.

13. The system of claim 12, wherein the etchant bath comprises an acid adapted to leach a metallic contaminant from the wafer.

14. The system of claim 12, wherein the grinder is a first grinder for performing a fine grind, and the system further comprises a second grinder adjacent to the first grinder and apart from the etchant bath, wherein the second grinder is a coarse grinder.

15. The system of claim 12, the system further comprising:
a microprocessor based controller; and
a database, wherein the database comprises code executable by the microprocessor based controller, and wherein the code executable by the microprocessor based controller controls movement of the transfer mechanism.

16. The system of claim 15, wherein the code executable by the microprocessor based controller further controls a time period which the wafer remains in the etchant bath.

17. A method for removing metallic contamination from ground wafers, the method comprising:
providing a wafer having a front, a back, and an edge;
grinding the wafer to flatten the wafer, wherein scratches on the surface of the wafer have a depth of ten microns or less; and
etching the wafer after grinding, wherein said etching removes less than approximately ten microns of wafer material from either the front or the back of the wafer, and wherein the etching leaches metal contaminants from the wafer such that a subsequent cleaning step is not required.

18. The method of claim 17, wherein etching the wafer is done in an acid bath.

19. The method of claim 18, wherein the metallic contamination comprises Iron or Copper, and wherein the acid bath leaches the Iron or Copper from the wafer.

20. The method of claim 17, wherein the etching removes less than about ten (10) microns of wafer material from the edge of the wafer.
